(19) United States
(12) Patent Application Publication
(10) Pub. No.: US 2011/0115573 A1
(43) Pub. Date: May 19, 2011

(54) BAND-PASS FILTER

(75) Inventors: ZHI-CHENG YU, Shenzhen City (CN); CHO-JU CHUNG, Tu-Cheng (TW)

(73) Assignees: AMBIT MICROSYSTEMS (SHANGHAI) LTD., SHANGHAI (CN); HON HAI PRECISION INDUSTRY CO., LTD., Tu-Cheng (TW)

(21) Appl. No.: 12/649,478

(22) Filed: Dec. 30, 2009

(30) Foreign Application Priority Data
Nov. 16, 2009 (CN) 200910309758.2

(51) Int. Cl. H03H 7/12

(52) U.S. Cl. 333/176

(57) ABSTRACT

A band-pass filter (BPF) includes a T-type lumped high pass filter and a hairpin-line resonator. The T-type lumped high pass filter is electrically connected with the T-type lumped high pass filter via a capacitor. The hairpin-line resonator includes a first hairpin-line low pass filter (LPF), and a second hairpin-line LPF connected in parallel to the first hairpin-line LPF reversely.

### BACKGROUND

1. Technical Field

Embodiments of the present disclosure generally relate to filters, and more particularly to a band-pass filter.

2. Description of Related Art

Many commonly used band-pass filters utilize low temperature co-fired ceramics (LTCC) technology to filter out noise. As shown in FIG. 1, one such band-pass filter is composed of relatively expensive multilayer LC chips. Another band-pass filter is composed of discrete components, as shown in FIG. 2, but occupies considerable space and exhibits less than desired performance.

What is needed, therefore, is an improved band-pass filter to overcome the limitations described.

### BRIEF DESCRIPTION OF THE DRAWINGS

FIG. 1 is a schematic diagram of a band-pass filter utilizing low temperature co-fired ceramics (LTCC) technology.

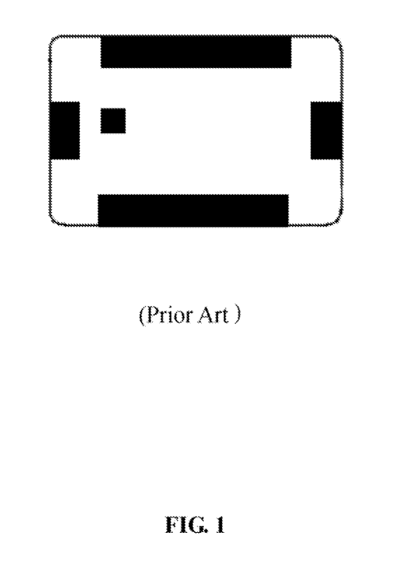

FIG. 2 is a schematic diagram of a band-pass filter using discrete components.

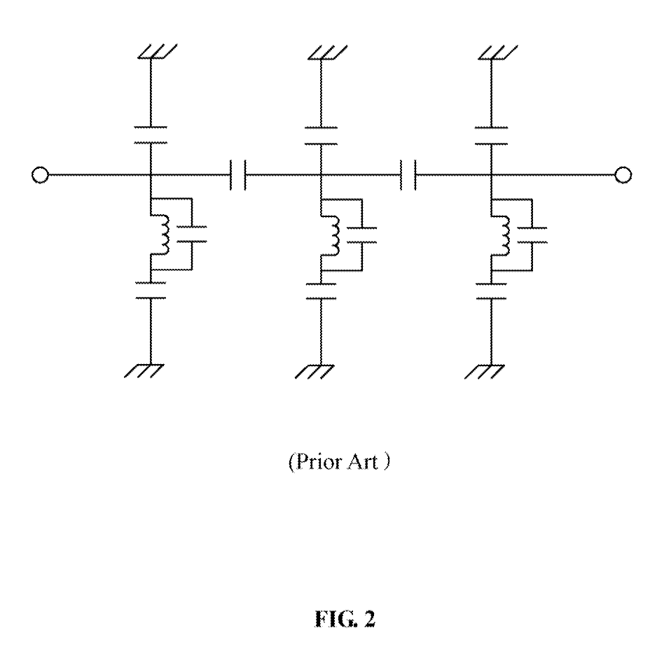

FIG. 3 is a circuit diagram of one embodiment of a band-pass filter.

FIG. 4 is a schematic diagram of a hairpin-line resonator in FIG. 3.

FIG. 5 is a schematic and graphical diagram of exemplary return and insertion losses for different frequencies of the band-pass filter of FIG. 3.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

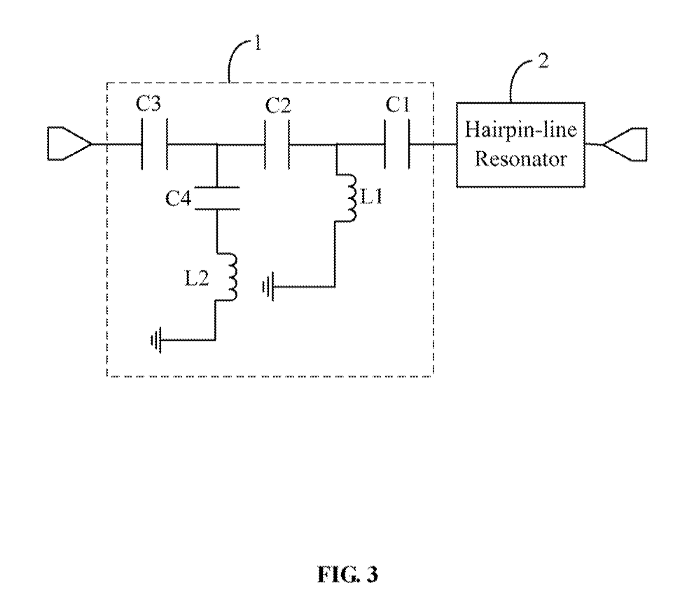

FIG. 3 is a circuit diagram of one embodiment of a band-pass filter (BPF) 10, which includes a T-type lumped high pass filter 1, and a hairpin-line resonator 2. In the embodiment, the hairpin-line resonator 2 is electrically connected to the T-type lumped high pass filter 1, and acts as a low pass filter.

In the embodiment, the T-type lumped high pass filter 1 includes a first capacitor “C1,” a second capacitor “C2,” a third capacitor “C3,” a fourth capacitor “C4,” a first inductor “L1,” and a second inductor “L2.” The first capacitor“C1,” the second capacitor“C2,” and the third capacitor “C3” are connected in series. One terminal of the inductor “L1” is electrically connected to a connection node of the first capacitor “C1” and the second capacitor“C2,” and the other terminal of the inductor “L1” is grounded. One terminal of the fourth capacitor “C4” is electrically connected to a connection node of the second capacitor “C2” and the third capacitor“C3,” and the other terminal of the fourth capacitor “C4” is grounded via the second inductor “L2.” In the embodiment, the T-type lumped high pass filter 1 and the hairpin-line resonator 2 are connected in series via the first capacitor “C1.”

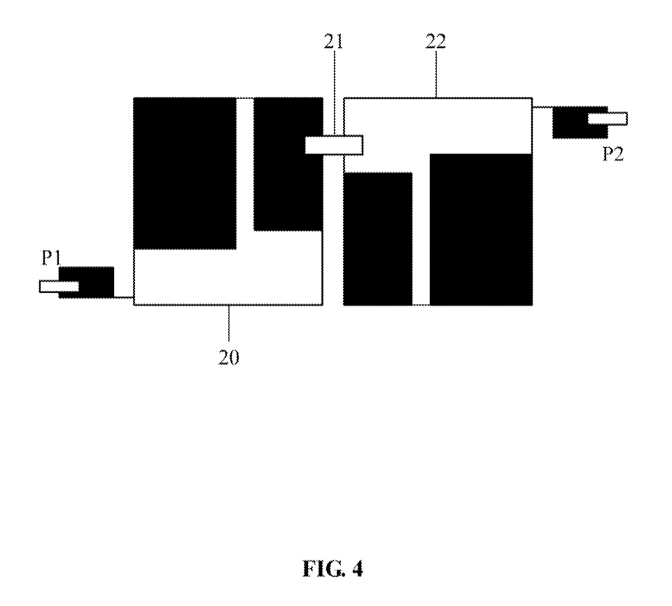

Referring to FIG. 4, the hairpin-line resonator 2 includes a first hairpin-line low pass filter (LPF) 20, a capacitor 21, and a second hairpin-line LPF 22. In the embodiment, the second hairpin-line LPF 22 is connected in parallel to the first hairpin-line LPF 20 reversely via the capacitor 21. With the structure of the hairpin-line resonator 2, about 30% bandwidth of the BPF 10 is obtained. With the capacitor 21, a tunable null point is added to obtain a designate out-band rejection of the BPF. By adjusting a capacitance of the capacitor 21, a transmission zero of the BPF 10 can be adjusted accordingly. That is, a tunable transmission zero can be obtained by adjusting the capacitance of the capacitor 21.

In one embodiment, the hairpin-line resonator 2 has two ports “P1” and “P2.” When the T-type lumped high pass filter 1 receives a series of radio frequency signals from an input port of BPF 10, the T-type lumped high pass filter 1 uses a first threshold frequency value to filter the radio frequency signals, so as to allow high frequency signals of the radio frequency signals to be transmitted to the first port “P1” of the hairpin-line resonator 2. In the embodiment, the first threshold frequency value may be predefined as a first frequency value “f1,” and the frequency value of each of the high frequency signals exceeds the first threshold frequency value “f1.” The hairpin-line resonator 2 receives the high frequency signals transmitted from the T-type lumped high pass filter 1 and uses a second threshold frequency value to filter the high frequency signals, to transmit low frequency signals through the port “P2.” In the embodiment, the second threshold frequency value may be predefined as a second frequency value “f2,” and the frequency value of each of the low frequency signals is less than the second threshold frequency “f2.” As such, the BPF 10 can obtain a series of band-pass signals by using the hairpin-line resonator 2. The band-pass signals may meet a pass band range “f2-f1.”

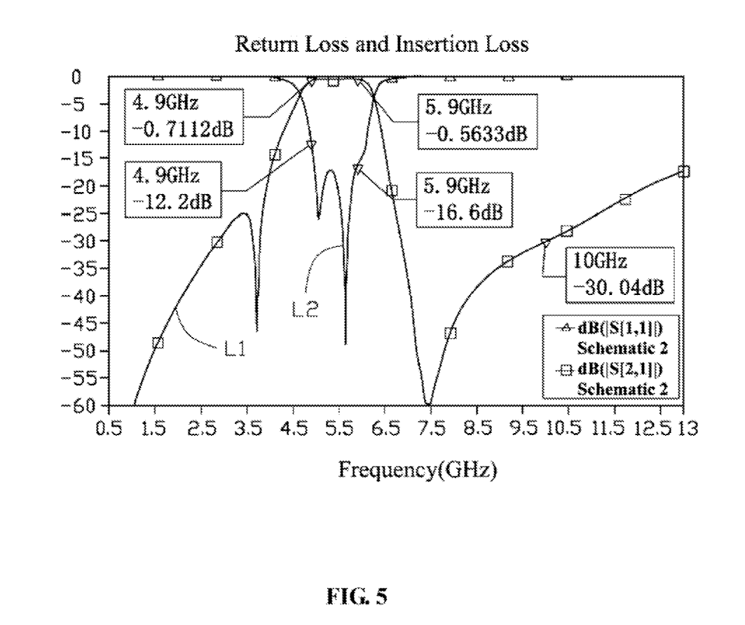

In one example with respect to FIG. 5, a schematic graph of an exemplary return loss and an insertion loss for different frequencies of the BPF 10, a transfer impendence of the radio frequency signals is 50Ω, each of the capacitors “C1,” “C3,” and “C4” is 1 pf, the capacitor “C2” is 0.5 pf, the first inductor “L1” is 2 nh (size: 1.797 mm*0.1778 mm), and the second inductor “L2” is 3.3 nh (size: 3.457 mm*0.1778 mm). Using the components to simulate the BPF 10, the simulation results are detailed as: the maximum Center Frequency is 5.4 GHz, the pass band range (BW) is “±0.5 GHz”, and the maximum insertion loss is 1.5 dB. When the frequency of the BPF is between 0.3 GHz˜0.4 GHz, an attenuation (absolute value) of the band-pass signals is 25.0 dB/min. When the frequency of the BPF is between 0.7 GHz˜0.8 GHz, the attenuation (absolute value) of the band-pass signals is 45.0 dB/min. As shown in FIG. 5, the curve “L1” indicates the schematic and graph diagram of the insertion loss at different frequencies, and the curve “L2” indicates the schematic and graph diagram of the return loss at the different frequencies. Two transmission zeroes, such as the lowest point of each of the curves “L1” and “L2,” are obtained. Using the two transmission zeroes, the pass band range is tunable.

As described, the BPF 10 of the preferred embodiment can achieve 5 GHz BPF, which supports all IEEE 802.11a wireless LAN products, such as a card-bus card, a mini-PCI module, and a access point.

Although certain inventive embodiments of the present disclosure have been specifically described, the present disclosure is not to be construed as being limited thereto. Various changes or modifications may be made to the present disclosure without departing from the scope and spirit of the present disclosure.

What is claimed is:

1. A band-pass filter (BPF), comprising:
a T-type lumped high pass filter; and
a hairpin-line resonator electrically connected to the T-type lumped high pass filter, the hairpin-line resonator comprising a first hairpin-line low pass filter (LPF), and a second hairpin-line LPF connected in parallel to the first hairpin-line LPF reversely via a capacitor.

2. The BPF as claimed in claim 1, wherein the capacitance of the capacitor is adjusted to obtain a tunable transmission zero of the BPF.

3. The BPF as claimed in claim 1, wherein the hairpin-line resonator is a low pass filter.

4. The BPF as claimed in claim 1, wherein the T-type lumped high pass filter comprises:
a first capacitor, a second capacitor, and a third capacitor connected in series;
an inductor, with one terminal electrically connected to a connection node of the first capacitor and second capacitor, and the other terminal grounded; and
a fourth capacitor, with one terminal electrically connected to a connection node of the second capacitor and the third capacitor, and the other grounded via a second inductor.

5. The BPF as claimed in claim 4, wherein the T-type lumped high pass filter and the hairpin-line resonator are connected in series via the first capacitor.

6. The BPF as claimed in claim 1, wherein the T-type lumped high pass filter receives a series of radio frequency signals from an input port of the BPF, and uses a first predefined threshold frequency value to filter the radio frequency signals and allow high frequency signals of the radio frequency signals to be transmitted to the hairpin-line resonator.

7. The BPF as claimed in claim 6, wherein the frequency value of each of the high frequency signals exceeds the first predefined threshold frequency value.

8. The BPF as claimed in claim 6, wherein the hairpin-line resonator receives the high frequency signals transmitted from the T-type lumped high pass filter, and uses a second threshold frequency value to filter the high frequency signals and allow low frequency signals to be transmitted through the BPF.

9. The BPF as claimed in claim 8, wherein the frequency value of each of the low frequency signals is less than the second predefined threshold frequency value.
